(19) United States
(12) Patent Application Publication
(10) Pub. No.: US 2025/0218948 A1
(43) Pub. Date: Jul. 3, 2025

(54) SEMICONDUCTOR DEVICE

(71) Applicant: AMAZING COOL TECHNOLOGY CORPORATION, Taipei City (TW)

(72) Inventors: Hsien-Tsung Tsai, Hsinchu City (TW); Yang-Ming Shih, Taichung City (TW); Hung-Yun Hsu, Hsinchu County (TW)

(73) Assignee: AMAZING COOL TECHNOLOGY CORPORATION, Taipei City (TW)

(21) Appl. No.: 18/900,852

(22) Filed: Sep. 29, 2024

(30) Foreign Application Priority Data
Dec. 29, 2023 (TW) 112151590

(51) Int. Cl. H01L 23/532; H01L 23/00

(52) U.S. Cl. CPC H01L 23/53276; H01L 23/53233; H01L 24/05; H01L 2224/05147; H01L 2224/05193

(57) ABSTRACT

A semiconductor device includes a substrate, an ILD layer on the substrate, a contact electrode unit with a gate wiring layer and contacts in the ILD layer, a lower IMD layer on the ILD layer, a wiring unit with lower and upper wiring layers disposed on the lower IMD layer and connected to the contacts, interconnect units stacked along a height direction on the wiring unit, including an upper IMD layer, lower and upper wiring layers and interconnects in the upper IMD layer and connected to each other; and a bonding pad unit including an insulating layer, interconnects and an upper wiring layer in the insulating layer connected to each other. The lower wiring layer is made of a graphene-copper composite material having graphene flakes covalently bonded and dispersed between copper atoms. The graphene content is less than 3 wt % and the oxygen content is no more than 10 ppm.

### BACKGROUND OF THE INVENTION

### 1. Field of the Invention

The present invention relates to the field of semiconductor technology, particularly to an advanced semiconductor device.

### 2. Description of the Prior Art

Semiconductor device dimensions have been decreasing year by year following Moore's Law, leading to the continuous advancement of integrated circuit (IC) manufacturing processes. It is well-known in the advanced IC manufacturing industry that when advanced IC processes reach the 7-nanometer node, resistance-capacitance (RC) delay has a significant impact on the operating speed of semiconductor devices. As semiconductor device lines are miniaturized, the layers of metal interconnect increases, and the spacing between conductors decreases. Therefore, the advanced IC manufacturing industry has an increasing demand for reducing RC delay to improve the operating speed of semiconductor devices.

FIG. 1 illustrates a conventional semiconductor device 1. The semiconductor device 1 includes a silicon substrate 11 with a source region 111 and a drain region 112 spaced apart, a contact electrode component 12 stacked on the silicon substrate 11, a circuit component 13 stacked on the contact electrode component 12, multiple interconnect components 14, and a bonding pad component 15. These interconnect components 14 are stacked in order along a height direction Z on the circuit component 13, and the bonding pad component 15 is stacked on the topmost interconnect component 14.

As shown in FIG. 1, the contact electrode component 12 includes an interlayer dielectric (ILD) layer 120 formed on the silicon substrate 11, a gate 121 located in the ILD layer 120, and a plurality of contacts 122 extending from the gate 121, the source region 111, and the drain region 112 to a surface of the ILD layer 120. The circuit component 13 includes a lower inter-metal dielectric (IMD) layer 130 and a copper (Cu) wiring layer 131 located in the lower IMD layer 130. The copper wiring layer 131 of the circuit component 13 corresponds to the contacts 122 of the contact electrode component 12. Each interconnect component 14 includes an upper IMD layer 140, a plurality of copper interconnects 141 located in each upper IMD layer 140, and a copper wiring layer 142 located in each upper IMD layer 140 and above the respective copper interconnects 141. The copper wiring layer 141 of the lowermost interconnect component 14 corresponds to the copper wiring layer 131 of the circuit component 13. The copper interconnects 141 of each interconnect component 14 correspond respectively to the copper wiring layers 142 of the upper and lower interconnect components 14. The bonding pad component 15 includes an oxide layer 150, a plurality of aluminum (Al) interconnects 151 located in the oxide layer 150 and corresponding to the copper wiring layer 142 of the uppermost interconnect component 14, and an aluminum wiring layer 152 extending from each aluminum interconnect 151 to a surface of the oxide layer 150.

As described above, in the conventional semiconductor device 1, copper and aluminum are commonly used as metal materials in the back-end of line (BEOL) process. Although copper and aluminum have good conductivity, their diffusion coefficients are relatively large, easily causing leakage current problems, which are undesirable in the industry. Therefore, in addition to using brittle low-k dielectric materials, the conventional semiconductor device 1 also requires denser barrier layers to prevent short circuits caused by leakage current. Specifically, as shown in FIG. 1, in order to reduce the diffusion of copper and aluminum in the conventional semiconductor device 1 to the lower IMD layer 130, the upper IMD layer 140, and the oxide layer 150, the circuit component 13 further includes a tantalum nitride (TaN) barrier layer 132 located between the lower IMD layer 130 and the patterned copper wiring layer 131; each interconnect component 14 further includes a tantalum nitride barrier layer 143 located between each upper IMD layer 140, copper interconnect 141, and copper wiring layer 142; and the bonding pad component 15 further includes a titanium nitride (TiN) barrier layer 153 located between the oxide layer 150, aluminum interconnect 151, and aluminum wiring layer 152. However, these TaN and TiN barrier layers increase the resistance of the conventional semiconductor device 1, thereby affecting the performance of the conventional semiconductor device 1.

As described above, improving the structure of semiconductor devices to solve the problems of leakage current and increased resistance caused by the miniaturization of semiconductor devices is a problem to be solved by relevant industries in the technical field.

### SUMMARY OF THE INVENTION

It is one object of the present invention to provide an advanced semiconductor device capable of solving problems such as leakage current and increased resistance caused by the miniaturization of semiconductor device and wirings.

In one aspect, the advanced semiconductor device of the present invention includes a substrate unit, a contact electrode unit, a wiring unit, a plurality of interconnect units, and a bonding pad unit.

The substrate unit includes a semiconductor substrate, a source region, and a drain region spaced apart in the semiconductor substrate.

The contact electrode unit includes an interlayer dielectric (ILD) layer disposed on the semiconductor substrate, a gate wiring layer and a plurality of contacts disposed in the ILD layer. The contacts extend from the source region, the drain region, and the gate wiring layer to a surface of the ILD layer, respectively.

The wiring unit includes a lower inter-metal dielectric (IMD) layer disposed on the surface of the ILD layer, a lower wiring layer disposed in the lower IMD layer and connected to the contacts, and an upper wiring layer disposed on and connected to the lower wiring layer of the wiring unit.

The interconnect units are stacked in order along a height direction on the wiring unit. Each interconnect unit includes an upper IMD layer, a lower wiring layer disposed in each upper IMD layer, a plurality of interconnects spaced apart and connected to the lower wiring layer of each interconnect unit, and an upper wiring layer disposed on and connected to the interconnects and the lower wiring layer of each interconnect unit. The lower wiring layer of the lowermost interconnect unit among the interconnect units is connected to the upper wiring layer of the wiring unit, and the lower wiring layers of the interconnect units above the lowermost interconnect unit are connected to the upper wiring layers of the interconnect units below them.

The bonding pad unit includes an insulating layer disposed on the uppermost interconnect unit among the interconnect units, a plurality of interconnects spaced apart in the insulating layer, and an upper wiring layer disposed on and connected to each interconnect of the bonding pad unit. Each interconnect of the bonding pad unit is electrically connected to the upper wiring layer of the uppermost interconnect unit.

According to some embodiments, the lower wiring layer of the wiring unit and the lower wiring layers of each interconnect unit are made of a graphene-copper composite material (graphene-Cu composites). The graphene has a plurality of graphene flakes. The graphene flakes are dispersed and arranged in gaps between adjacent copper atoms. Covalent bonds exist between the graphene flakes. Based on the total weight of the graphene-copper composite material, the graphene content is less than 3 wt %, and the oxygen content in the graphene-copper composite material is no more than 10 ppm.

The effect of the present invention is that the graphene-copper composite material has a low resistance due to its oxygen content being no more than 10 ppm, and the graphene flakes in the graphene-copper composite material have high stability because they are dispersed and arranged in the gaps between adjacent copper atoms and form bonds with each other, so that the graphene-copper composite material used in the lower wiring layer of the wiring unit and the lower wiring layers of each interconnect unit can effectively suppress the diffusion of copper to the lower inter-metal dielectric layer, the upper inter-metal dielectric layer, and the insulating layer, thereby solving the problem of leakage current.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The other features and advantages of the present invention will be clearly presented in the embodiments with reference to the drawings, wherein:

FIG. 1 is a schematic diagram illustrating a conventional semiconductor device;

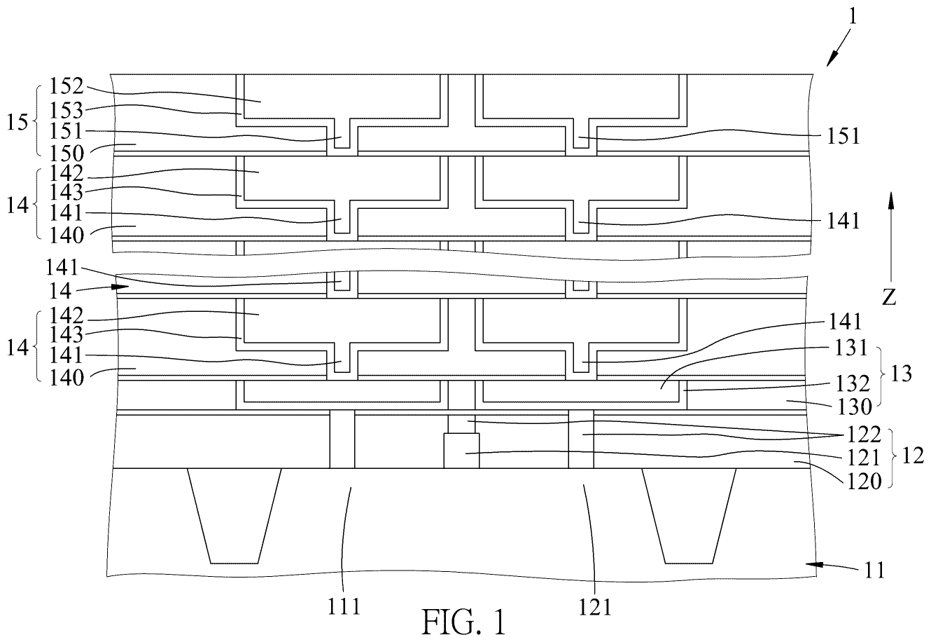

FIG. 2 is a schematic diagram illustrating a first embodiment of the advanced semiconductor device of the present invention;

FIG. 3 is a schematic diagram illustrating a second embodiment of the advanced semiconductor device of the present invention;

FIG. 4 is a schematic diagram illustrating a third embodiment of the advanced semiconductor device of the present invention; and

FIG. 5 is a schematic diagram illustrating a fourth embodiment of the advanced semiconductor device of the present invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced. It is to be understood that similar elements are indicated by the same reference numerals in the following description.

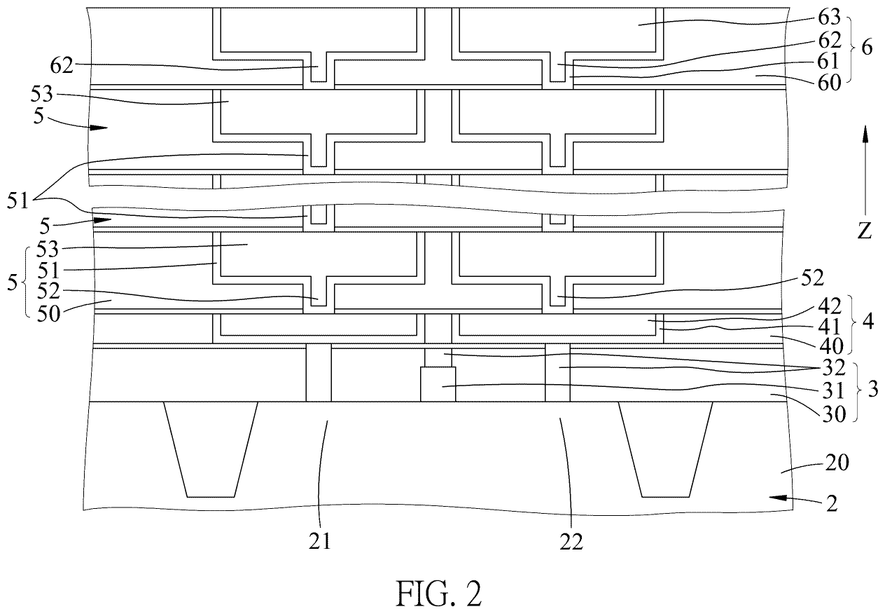

Referring to FIG. 2, a first embodiment of the advanced semiconductor device of the present invention is substantially comprised of: a substrate unit 2, a contact electrode unit 3, a wiring unit 4, a plurality of interconnect units 5, and a bonding pad unit 6.

The substrate unit 2 includes a semiconductor substrate 20, a source region 21, and a drain region 22 spaced apart in the semiconductor substrate 20. In this first embodiment of the invention, the semiconductor substrate 20 is exemplified by a silicon substrate, but is not limited thereto.

The contact electrode unit 3 includes an interlayer dielectric (ILD) layer 30 disposed on the semiconductor substrate 20, a gate wiring layer 31 and a plurality of contacts 32 disposed in the ILD layer 30. The contacts 32 extend from the source region 21, the drain region 22, and the gate wiring layer 31 to a surface of the ILD layer 30, respectively.

The wiring unit 4 includes a lower inter-metal dielectric (IMD) layer 40 disposed on the surface of the ILD layer 30, a lower wiring layer 41 disposed in the lower IMD layer 40 and connected to the contacts 32, and an upper wiring layer 42 disposed on and connected to the lower wiring layer 41 of the wiring unit 4.

The interconnect units 5 are stacked in order along a height direction Z on the wiring unit 4. Each interconnect unit 5 includes an upper IMD layer 50, a lower wiring layer 51 disposed in each upper IMD layer 50, a plurality of interconnects spaced apart and connected to the lower wiring layer 51 of each interconnect unit 5, and an upper wiring layer 53 disposed on and connected to the interconnects and the lower wiring layer 51 of each interconnect unit 5. The lower wiring layer 51 of the lowermost interconnect unit 5 among the interconnect units 5 is connected to the upper wiring layer 42 of the wiring unit 4, and the lower wiring layers 51 of the interconnect units 5 above the lowermost interconnect unit 5 are connected to the upper wiring layers 53 of the interconnect units 5 below them.

The bonding pad unit 6 includes an insulating layer 60 disposed on the uppermost interconnect unit 5 among the interconnect units 5, a plurality of interconnects 62 spaced apart in the insulating layer 60, and an upper wiring layer 63 disposed on and connected to each interconnect of the bonding pad unit 6. Each interconnect 62 of the bonding pad unit 6 is electrically connected to the upper wiring layer 53 of the uppermost interconnect unit 5. In this first embodiment of the invention, the bonding pad unit 6 further includes a lower wiring layer 61 disposed in the insulating layer 60. The lower wiring layer 61 of the bonding pad unit 6 is interposed between the insulating layer 60 and each interconnect 62 and upper wiring layer 63 of the bonding pad unit 6 to connect each interconnect 62 and upper wiring layer 63 of the bonding pad unit 6 and to the upper wiring layer 53 of the uppermost interconnect unit 5.

In this first embodiment of the invention, the lower wiring layer 41 of the wiring unit 4, the lower wiring layers 51 of each interconnect unit 5, and the lower wiring layer 61 of the bonding pad unit 6 are made of a graphene-copper composite material, the upper wiring layer 42 of the wiring unit 4, the interconnects 52 and upper wiring layers 53 of each interconnect unit 5 are exemplified by copper, and the insulating layer 60 and interconnects 62 and upper wiring layer 63 of the bonding pad unit 6 are exemplified by oxide layer and aluminum, respectively. Specifically, the graphene of the graphene-copper composite material has a plurality of graphene flakes. The graphene flakes are dispersed and arranged in gaps between adjacent copper atoms. Covalent bonds exist between the graphene flakes. Based on the total weight of the graphene-copper composite material, the graphene content is less than 3 wt %, and the oxygen content in the graphene-copper composite material is no more than 10 ppm. Preferably, the graphene content in the graphene-copper composite material is between 0.02 wt % and 0.5 wt %.

The method for manufacturing the graphene-copper composite material described above is detailed as follows, which includes, in order, a step a, a step b, a step c, a step d, a step e, a step f, and a step g.

The step a is to provide a composition containing copper powder, modified graphene flakes, and a binder. The binder suitable for the composition of the first embodiment of the present invention contains 0.5 to 2.0 wt % of a coupling agent, 5 to 20 wt % of a dispersant, and a balance of wax or a low molecular weight thermoplastic polymer. The coupling agent can be selected from titanates or organic chromium compounds; the dispersant can be methylcyclopentadienol, polyacrylamide, or a fatty acid polyethylene glycol ester; the wax can be a general paraffin wax, microcrystalline wax; and the low molecular weight thermoplastic polymer can be acrylic. In addition, the modified graphene flakes refer to graphene molecules in which at least one carbon atom is covalently bonded to a functional group; wherein the functional group is preferably an oxygen-containing or nitrogen-containing functional group. The functional group suitable for the present invention is selected from fatty acids, such as stearic acid. It should be noted that since both titanates and organic chromium compounds have strong peripheral electron bonding forces, the bonding strength between graphene molecules and copper can be enhanced through the coupling agent. For example, titanates can have the advantage of being lightweight, and organic chromium compounds (organic chromium coordination compounds) can form more bonds due to their side chains. In addition, the dispersant and wax can effectively assist in the dispersion of graphene flakes and stabilize the dispersed graphene flakes. In the first embodiment of the present invention, the copper powder is MA-CC-S copper powder purchased from Mitsui Kinzoku ACT Corporation of Japan; the modified graphene flakes are P-PG 20 graphene purchased from EnerAge Inc.

The step b is to disperse the composition by means of planetary ball milling so that the copper powder and graphene flakes can be uniformly dispersed in the dispersant and coated with the wax to form a composite powder. Specifically, the stearic acid functional group linked to the graphene molecule of the modified graphene flakes can cause the graphene flakes to have the same type of charge, causing electrostatic repulsion between the graphene flakes. In this way, the graphene flakes can be uniformly dispersed in the coupling agent, dispersant, and wax. In addition, the planetary ball milling process causes the modified graphene flakes to generate frictional heat, causing the sp3 bond of the stearic acid functional group linked to carbon atoms of the graphene flake to break due to heat absorption. Therefore, the sp3 bond of the carbon atom of the graphene flake that has been broken can immediately re-bond with the sp3 bond of the carbon atom of another graphene flake that has been broken, and at the same time, the coupling agent is used to assist the bonding between the aforementioned broken graphene flakes and copper powder, so that the graphene flakes are connected to each other in a planar manner and layer by layer to wrap each copper powder to form the composite powder.

The step c is to heat the composite powder to form a liquid mixed raw material containing copper powder, graphene flakes, and a liquid binder.

The step d is to inject the liquid mixed raw material into a cold isostatic pressing mold and apply cold isostatic pressing to the liquid mixed raw material to solidify it into a green body.

The step e is to perform a debinding process on the green body at a temperature of 140-170° C. using an inert gas as a fluid medium to remove the binder from the green body and form a debinding semi-finished product. Specifically, the temperature conditions implemented in the debinding process can crack and vaporize the binder in the green body, and the fluid medium carries the vaporized binder out of the green body to form the debinding semi-finished product.

The step f involves sintering the debindered semi-finished product at a temperature of 1050° C. in a nitrogen or hydrogen atmosphere for 1 hour, causing the copper powder in the debindered semi-finished product to melt and bond together to form a copper body, and the graphene flakes in the debindered semi-finished product are dispersed in the copper body to form a graphene-copper composite semi-finished product. It should be noted here that due to the fact that the carbon atoms in graphene molecules form a honeycomb lattice structure through their own sp2 hybrid orbitals, they exhibit a two-dimensional structure. Therefore, after sintering, the graphene molecules are dispersed and arranged in the gaps between the copper atoms in the copper lattice, and bonds are formed between them, which can improve the high stability of the graphene-copper composite semi-finished product.

In step g, the graphene-copper composite semi-finished product is subjected to vacuum melting at a temperature of 1300° C. under a nitrogen atmosphere to produce the graphene-copper composite material of the first embodiment of the present invention. It should be noted here that, considering that after planetary ball milling, graphene molecules that do not form bonds with other graphene molecules or copper atoms are distributed more randomly in the graphene-copper composite semi-finished product after sintering. Therefore, through vacuum melting, the graphene-copper composite semi-finished product can be melted into a copper melt containing graphene flakes, allowing the graphene flakes to be evenly dispersed in the copper melt. In addition, since the surface of the copper powder is easily oxidized to copper oxide, the vacuum melting process in step g can further reduce the copper oxide, reducing the oxygen content in the graphene-copper composite material to no more than 10 ppm.

After the vacuum melting process of step g is completed, the graphene-copper composite material of the first embodiment of the present invention is tested with an oxygen-nitrogen-hydrogen analyzer, model EMGA 930, according to the ASTM E 2575-19 standard, and the results show that the oxygen content is only 6.0 ppm. In addition, the graphene-copper composite material has a thermal conductivity of no less than 460 W/mK.

Specifically, in the first embodiment of the present invention, the graphene-copper composite material is used as a cathode target for a sputtering apparatus. The lower wiring layer 41 of the wiring unit 4, the lower wiring layers 51 of each interconnect unit 5, and the lower wiring layer 61 of the bonding pad unit 6 are sputtered from the cathode target of the sputtering apparatus.

As can be seen from the detailed description of the first embodiment of the present invention, the graphene-copper composite material has the characteristics of being resistant to oxidation, having low resistance (high conductivity), and having a low coefficient of thermal expansion, which solves the problem of high resistance caused by line miniaturization. In addition, the graphene molecules in the graphene-copper composite material are dispersed and arranged in the gaps between the copper atoms in the copper lattice and form bonds with each other. Therefore, the graphene-copper composite material has high stability. The graphene-copper composite material used in the lower wiring layer 41 of the wiring unit 4, the lower wiring layers 51 of each interconnect unit 5, and the lower wiring layer 61 of the bonding pad unit 6 in the first embodiment of the present invention can effectively suppress the diffusion of copper to the lower inter-metal dielectric (IMD) layer 40, the upper inter-metal dielectric (IMD) layer 50, and the insulating layer 50. Therefore, the graphene-copper composite material of the first embodiment of the present invention can effectively suppress the leakage current problem, and the lower wiring layers 41, 51, and 61 of the first embodiment can even replace the conventional tantalum nitride barrier layer 132, 143, and titanium nitride barrier layer 153, and even eliminate the need for brittle low-k dielectric materials.

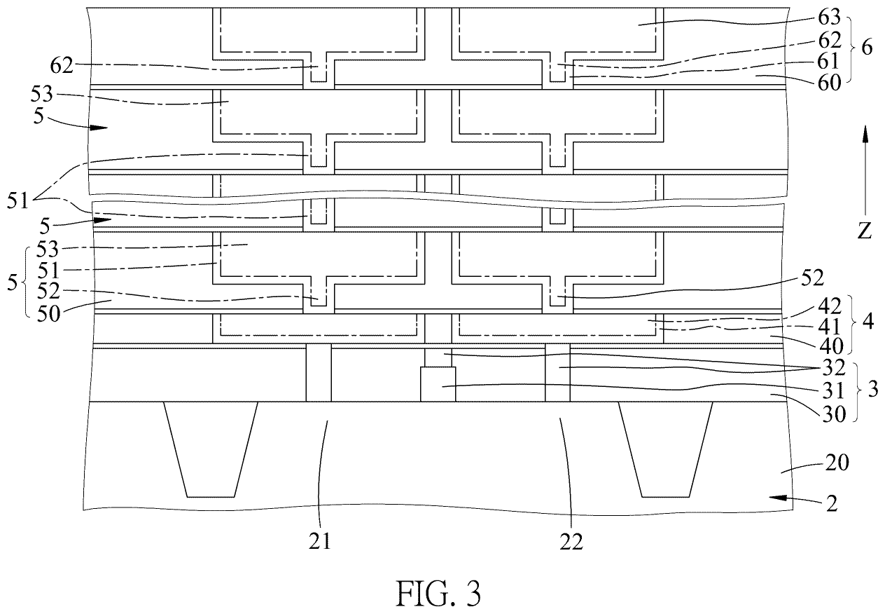

Referring to FIG. 3, a second embodiment of the advanced semiconductor device of the present invention is substantially the same as the first embodiment, except that the upper wiring layer 42 of the wiring unit 4 is made of the graphene-copper composite material, and the interconnects 52 and upper wiring layers 53 of each interconnect unit 5 are also made of the graphene-copper composite material. Thus, in the advanced semiconductor device of the second embodiment of the present invention, the wiring unit 4 and each interconnect unit 5 are both made of the graphene-copper composite material, which not only solves the problems of high resistance and leakage current, but also, due to the low coefficient of thermal expansion and high thermal conductivity of the graphene-copper composite material, makes it more stable in actual operation.

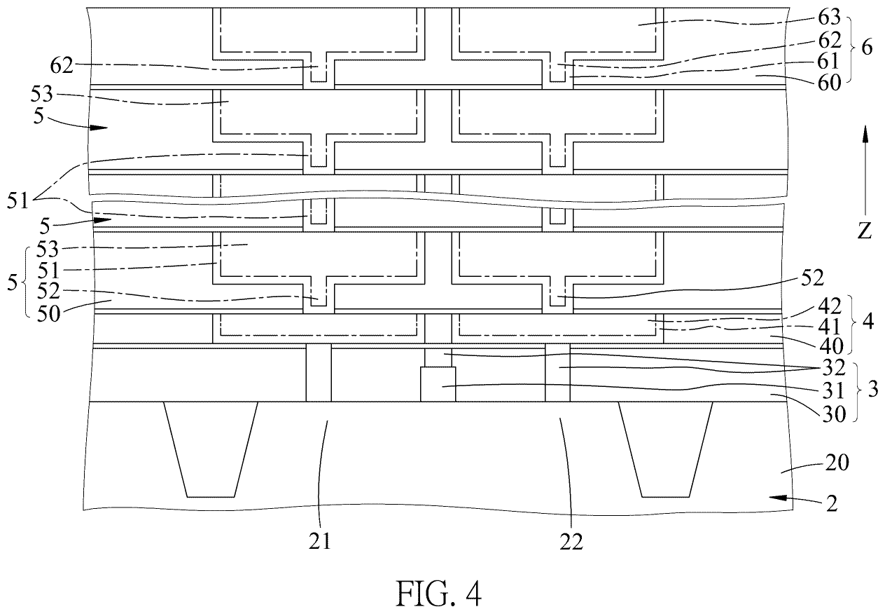

Referring to FIG. 4, a third embodiment of the advanced semiconductor device of the present invention is substantially the same as the second embodiment, except that the interconnects 62 and upper wiring layer 63 of the bonding pad unit 6 are made of the graphene-copper composite material. Thus, in the advanced semiconductor device of the third embodiment of the present invention, under the premise that the wiring unit 4, each interconnect unit 5, and the bonding pad unit 6 are all made of the graphene-copper composite material, it can not only solve the problems of high resistance and leakage current, but also, due to the low coefficient of thermal expansion and high thermal conductivity of the graphene-copper composite material, it is more stable in actual operation and is more suitable for the 2 nm node process.

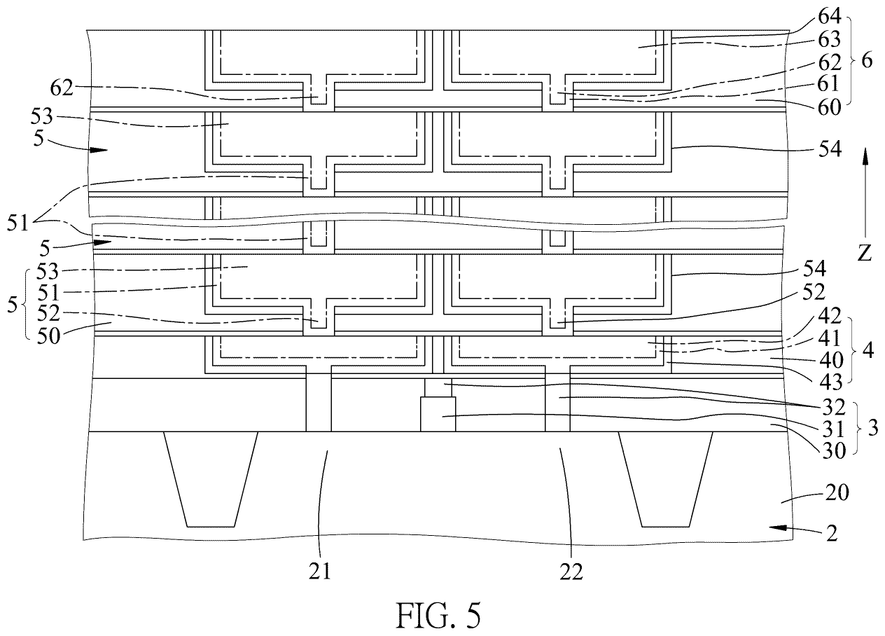

Referring to FIG. 5, a fourth embodiment of the advanced semiconductor device of the present invention is substantially the same as the third embodiment, except that the wiring unit 4 further includes a barrier layer 43 having a plurality of spaced vias, each interconnect unit 5 further includes a barrier layer 54 having a plurality of spaced vias, and the bonding pad unit 6 further includes a barrier layer 64 having a plurality of spaced vias.

Specifically, the barrier layer 43 of the wiring unit 4 in the fourth embodiment is disposed in the lower inter-metal dielectric (IMD) layer 40 of the wiring unit 4, between the lower inter-metal dielectric layer 40 and the lower wiring layer 41 of the wiring unit 4. The lower wiring layer 41 of the wiring unit 4 fills the vias of the barrier layer 43 of the wiring unit 4, thereby connecting the contacts 32 of the contact electrode unit 3.

The barrier layer 54 of each interconnect unit 5 in the fourth embodiment is located between the respective upper inter-metal dielectric (IMD) layer 50 and the respective lower wiring layer 51. The lower wiring layer 51 of each interconnect unit 5 fills the vias of its respective barrier layer 54. Thus, the lowermost interconnect unit 5 among the interconnect units 5 can be connected to the upper wiring layer 42 of the wiring unit 4 through the lower wiring layer 51 at the vias of its barrier layer 54, and the interconnect units 5 above the lowermost interconnect unit 5 can be connected to the upper wiring layer 53 of the interconnect unit 5 below it through the lower wiring layer 51 at the vias of its barrier layer 54.

The barrier layer 64 of the bonding pad unit 6 in the fourth embodiment is disposed in the insulating layer 60 of the bonding pad unit 6, between the insulating layer 60 of the bonding pad unit 6 and the lower wiring layer 61 of the bonding pad unit 6. The lower wiring layer 61 of the bonding pad unit 6 fills the vias of its barrier layer 64, thereby connecting to the upper wiring layer 53 of the uppermost interconnect unit 5.

In summary, the wiring unit 4, each interconnect unit 5, and the bonding pad unit 6 of the advanced semiconductor device of the present invention can solve the problems of high resistance and leakage current due to the characteristics of the graphene-copper composite material, so as to be more stable in actual operation, thus truly achieving the object of the present invention.

While the foregoing description is only an embodiment of the present invention, it should not be construed as limiting the scope of the present invention. Any simple equivalent variations and modifications made in accordance with the scope of the claims and the specification of the present invention are still within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate unit, including a semiconductor substrate, a source region, and a drain region spaced apart in the semiconductor substrate;
a contact electrode unit, including an interlayer dielectric disposed on the semiconductor substrate, a gate wiring layer and a plurality of contacts disposed in the interlayer dielectric, wherein the contacts extend from the source region, the drain region, and the gate wiring layer to a surface of the interlayer dielectric;
a wiring unit, including a lower inter-metal dielectric disposed on the surface of the interlayer dielectric, a lower wiring layer disposed in the lower inter-metal dielectric and connected to the contacts, and an upper wiring layer disposed on and connected to the lower wiring layer of the wiring unit;
a plurality of interconnect units, stacked in order along a height direction on the wiring unit, wherein each interconnect unit includes an upper inter-metal dielectric, a lower wiring layer disposed in each upper inter-metal dielectric, a plurality of interconnects spaced apart and connected to the lower wiring layer of each interconnect unit, and an upper wiring layer disposed on and connected to the interconnects and the lower wiring layer of each interconnect unit, wherein the lower wiring layer of the lowermost interconnect unit among the interconnect units is connected to the upper wiring layer of the wiring unit, and the lower wiring layers of the interconnect units above the lowermost interconnect unit are connected to the upper wiring layers of the interconnect units below them; and
a bonding pad unit, including an insulating layer disposed on the uppermost interconnect unit among the interconnect units, a plurality of interconnects spaced apart in the insulating layer, and an upper wiring layer disposed on and connected to each interconnect of the bonding pad unit, wherein each interconnect of the bonding pad unit is electrically connected to the upper wiring layer of the uppermost interconnect unit;
wherein the lower wiring layer of the wiring unit and the lower wiring layers of each interconnect unit are made of a graphene-copper composite material containing graphene flakes;
wherein the graphene flakes are dispersed and arranged in gaps between adjacent copper atoms, and covalent bonds exist between the graphene flakes, wherein, based on the total weight of the graphene-copper composite material, the graphene content is less than 3 wt %, and the oxygen content in the graphene-copper composite material is no more than 10 ppm.

2. The semiconductor device of claim 1, wherein the upper wiring layer of the wiring unit is made of the graphene-copper composite material, and the interconnects and upper wiring layers of each interconnect unit are made of the graphene-copper composite material.

3. The semiconductor device of claim 2, wherein the interconnects and upper wiring layer of the bonding pad unit are made of the graphene-copper composite material.

4. The semiconductor device of claim 3, wherein the wiring unit further includes a barrier layer having a plurality of spaced vias, the barrier layer of the wiring unit is disposed in the lower inter-metal dielectric of the wiring unit, between the lower inter-metal dielectric and the lower wiring layer, and the lower wiring layer of the wiring unit fills the vias of the barrier layer of the wiring unit to connect the contacts of the contact electrode unit; each interconnect unit further includes a barrier layer having a plurality of spaced vias, the barrier layer of each interconnect unit is located between the respective upper inter-metal dielectric and the respective lower wiring layer, and the lower wiring layer of each interconnect unit fills the vias of its respective barrier layer.

5. The semiconductor device of claim 1, wherein the bonding pad unit further includes a lower wiring layer disposed in the insulating layer, the lower wiring layer of the bonding pad unit is interposed between the insulating layer and each interconnect and upper wiring layer of the bonding pad unit, to connect each interconnect and upper wiring layer of the bonding pad unit and to be connected to the upper wiring layer of the uppermost interconnect unit, and the lower wiring layer of the bonding pad unit is made of the graphene-copper composite material.

6. The semiconductor device of claim 5, wherein the bonding pad unit further includes a barrier layer having a plurality of spaced vias, the barrier layer of the bonding pad unit is disposed in the insulating layer of the bonding pad unit, between the insulating layer of the bonding pad unit and the lower wiring layer of the bonding pad unit, and the lower wiring layer of the bonding pad unit fills the vias of its barrier layer to connect the upper wiring layer of the uppermost interconnect unit.

7. The semiconductor device of claim 1, wherein the graphene-copper composite material has a thermal conductivity of no less than 460 W/mK.
